(19) United States
(12) Patent Application Publication
(10) Pub. No.: US 2025/0329535 A1
(43) Pub. Date: Oct. 23, 2025

(54) METHOD INCLUDING AN ION BEAM IMPLANT AND STRESSED FILM FOR SEPARATING A SUBSTRATE FILM REGION FROM A BULK SUBSTRATE REGION

(71) Applicant: Microchip Technology Incorporated, Chandler, AZ (US)

(72) Inventor: Sergey Maximenko, Colorado Springs, CO (US)

(73) Assignee: Microchip Technology Incorporated, Chandler, AZ (US)

(21) Appl. No.: 18/747,833

(22) Filed: Jun. 19, 2024

Related U.S. Application Data
(60) Provisional application No. 63/637,408, filed on Apr. 23, 2024.

(51) Int. Cl. H01L 21/265; H01L 21/324; H01L 21/70; H01L 21/762

(52) U.S. Cl. CPC H01L 21/26513; H01L 21/324; H01L 21/702; H01L 21/76254

(57) ABSTRACT

A method comprises performing an ion beam implant in a semiconductor substrate to form an ion-induced damage layer at an implant depth in the semiconductor substrate, wherein a portion of the substrate above the ion-induced damage layer defines a substrate film region, a portion of the substrate below the ion-induced damage layer defines a bulk substrate region. Semiconductor device components are formed on the substrate film region, defining a substrate film-based semiconductor device structure. A stressed film is formed on the semiconductor device components, which introduces internal forces in the substrate film-based semiconductor device structure. The substrate film-based semiconductor device structure is separated from the bulk substrate region at the ion-induced damage layer, wherein the separation is facilitated by (a) the ion-induced damage layer and (b) the internal forces introduced by the stressed film. The separated substrate film-based semiconductor device structure may be mounted on a carrier.

### RELATED APPLICATION

This application claims priority to commonly owned U.S. Provisional Patent Application No. 63/637,408 filed Apr. 23, 2024, the entire contents of which are hereby incorporated by reference for all purposes.

### TECHNICAL FIELD

The present disclosure relates to a method including an ion beam implant and a stressed film to facilitate separation of a substrate film region (having semiconductor device components formed thereon) from an underlying bulk substrate region.

### BACKGROUND

In conventional manufacturing of semiconductor devices formed on certain substrates, for example silicon carbide (SiC), gallium nitride (GaN), diamond, or other expensive substrates, semiconductor devices (e.g., transistors) are formed on a thin substrate film (e.g., a thin SiC, GaN, or diamond film) attached to an inexpensive substrate carrier, to control costs. However, producing devices on a thin substrate film often results in waferbowing and/or wrapping of the structure, which may hinder the fabrication of device structures with consistent electrical characteristics across a wafer.

There is a need for improved production of semiconductor devices on a thin substrate, for example a thin SiC, GaN, or diamond substrate.

### SUMMARY

The present disclosure provides methods for forming semiconductor device structures on a semiconductor substrate (e.g., a silicon carbide (SiC), gallium nitride (GaN), or diamond substrate) before reducing a thickness of the substrate, e.g., by detaching (separating) a thin layer of the substrate from a thicker bulk region of the substrate. In some examples, an ion beam implantation is performed in the substrate to form a ion-induced damage layer a partial depth in the substrate to define (a) an substrate film region above the damage layer and (b) a bulk substrate region below the damage layer, wherein the damaged structure of the ion-induced damage layer facilitates a subsequent separation—after forming semiconductor device structures on the substrate film region—of the substrate film region (having semiconductor device structures formed thereon) from the underlying bulk substrate region. In other words, the structure may separate at the weakened ion-induced damage layer.

In some examples, a stressed film, for example comprising silicon nitride (SiNₓ), may be formed on the semiconductor device structures formed on the substrate film region. The stressed film may have inherent internal force (e.g., tensile stresses and/or compressive stresses), and may impart these internal forces into the semiconductor device structures, the substrate film region, and/or the ion-induced damage layer. These imparted internal forces (e.g., tensile stresses and/or compressive stresses) may further facilitate the separation of the substrate film region (having semiconductor device structures formed thereon) from the underlying bulk substrate region.

The separated substrate film region with semiconductor device structures formed thereon may be attached to a high electrical/thermal conductivity die carrier to construct a completed device.

In some examples, the separated bulk substrate region of the semiconductor substrate may be reused multiple times to produce additional devices, wherein a thin region (layer) of the semiconductor substrate is removed during each iteration of the process.

The disclosed methods may be used to create device structures from SiC, GaN, or diamond or other semiconductor materials, for example for highly conductive electrical/thermal and cost-efficient substrates. The disclosed methods may be used, for example, for high-power switching structures composed of SiC or GaN or diamond.

In some examples, the disclosed methods may reduce the cost of single crystal SiC substrates and improve electrical device performance of resulting devices.

One aspect provides a method including performing an ion beam implant in a semiconductor substrate to form an ion-induced damage layer at an implant depth in the semiconductor substrate, wherein a portion of the semiconductor substrate above the ion-induced damage layer defines a substrate film region, a portion of the semiconductor substrate below the ion-induced damage layer defines a bulk substrate region, and the ion-induced damage layer has a damaged structure relative to the substrate film region and the bulk substrate region. Semiconductor device components are formed on the substrate film region, wherein the substrate film region and the semiconductor device components formed thereon define a substrate film-based semiconductor device structure. A stressed film is formed on the semiconductor device components, wherein the stressed film introduces internal forces in the substrate film-based semiconductor device structure. The substrate film-based semiconductor device structure is separated from the bulk substrate region at the ion-induced damage layer, wherein the separation is facilitated by (a) the damaged structure of the ion-induced damage layer and (b) the internal forces introduced in the substrate film-based semiconductor device structure by the stressed film. The separated substrate film-based semiconductor device structure is mounted on a carrier to define a mounted device structure.

In some examples, the method includes securing a transfer device to the stressed film prior to separating the substrate film-based semiconductor device structure from the bulk substrate region, and removing the transfer device after mounting the separated substrate film-based semiconductor device structure on the carrier.

In some examples, the semiconductor substrate comprises silicon carbide, gallium nitride, or diamond.

In some examples, the implant depth of the ion-induced damage layer is in the range of 0.35-1.0 μm below an upper surface of the semiconductor substrate.

In some examples, the method includes removing the stressed film from the semiconductor device components.

In some examples, the method includes dicing the mounted device structure to form a plurality of discrete devices.

In some examples, forming the stressed film on the semiconductor device components comprises depositing a conformal dielectric material over the semiconductor device components.

In some examples, forming the stressed film on the semiconductor device components comprises attaching a pre-formed stressed film to the semiconductor device components.

In some examples, the stressed film comprises silicon nitride.

In some examples, forming semiconductor device components on the substrate film region comprises growing an epitaxial region over the substrate film region and forming metal structures over the epitaxial region.

In some examples, the method includes, after separating the substrate film-based semiconductor device structure from the bulk substrate region, using the separated bulk substrate region to form additional devices.

One aspect provides a method including forming semiconductor device components on a semiconductor substrate to define a semiconductor device structure; forming a stressed film over the semiconductor device components, wherein the stressed film introduces internal forces in a substrate film region of the semiconductor substrate; separating a substrate film region of the semiconductor substrate from an underlying bulk substrate region of the semiconductor substrate, the separated substrate film region carrying the semiconductor device components to collectively define a substrate film-based semiconductor device structure, wherein the separation of the substrate film region from the underlying bulk substrate region is facilitated by the internal forces introduced in the substrate film region of the semiconductor substrate by the stressed film; and mounting the separated substrate film-based semiconductor device structure on a carrier.

In some examples, the stressed film comprises silicon nitride.

In some examples, the method includes performing an ion beam implant in the semiconductor substrate to form an ion-induced damage layer at an implant depth in the semiconductor substrate, wherein a portion of the semiconductor substrate above the ion-induced damage layer defines the substrate film region, and a portion of the semiconductor substrate below the ion-induced damage layer defines the bulk substrate region, wherein the ion-induced damage layer has a damaged structure relative to the substrate film region and the bulk substrate region.

In some examples, the separation of the substrate film region from the underlying bulk substrate region is facilitated by the damaged structure of the ion-induced damage layer.

In some examples, forming the stressed film over the semiconductor device components comprises depositing a conformal dielectric material over the semiconductor device components.

In some examples, the method includes securing a transfer device to the stressed film prior to separating the substrate film region from the underlying bulk substrate region, and removing the transfer device after mounting the separated substrate film-based semiconductor device structure on the carrier.

In some examples, forming semiconductor device components on the semiconductor substrate comprises growing an epitaxial region over the substrate film region, and forming metal structures over the epitaxial region.

One aspect provides a device structure formed by a process including performing an ion beam implant in a semiconductor substrate to form an ion-induced damage layer at an implant depth in the semiconductor substrate, wherein a portion of the semiconductor substrate above the ion-induced damage layer defines a substrate film region, a portion of the semiconductor substrate below the ion-induced damage layer defines a bulk substrate region, and the ion-induced damage layer has a damaged structure relative to the substrate film region and the bulk substrate region; forming semiconductor device components on the substrate film region, wherein the substrate film region and the semiconductor device components formed thereon define a substrate film-based semiconductor device structure; forming a stressed film on the semiconductor device components, wherein the stressed film introduces internal forces in the substrate film-based semiconductor device structure; separating the substrate film-based semiconductor device structure from the bulk substrate region at the ion-induced damage layer, wherein the separation is facilitated by (a) the damaged structure of the ion-induced damage layer and (b) the internal forces introduced in the substrate film-based semiconductor device structure by the stressed film; and mounting the separated substrate film-based semiconductor device structure on a carrier to define a mounted device structure.

### BRIEF DESCRIPTION OF THE DRAWINGS

Example aspects of the present disclosure are described below in conjunction with the figures, in which:

FIG. 1 is a flowchart showing an example method of forming semiconductor devices; and

FIGS. 2A-2G are a series of cross-sectional side views illustrating an example method for forming semiconductor devices.

It should be understood that the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

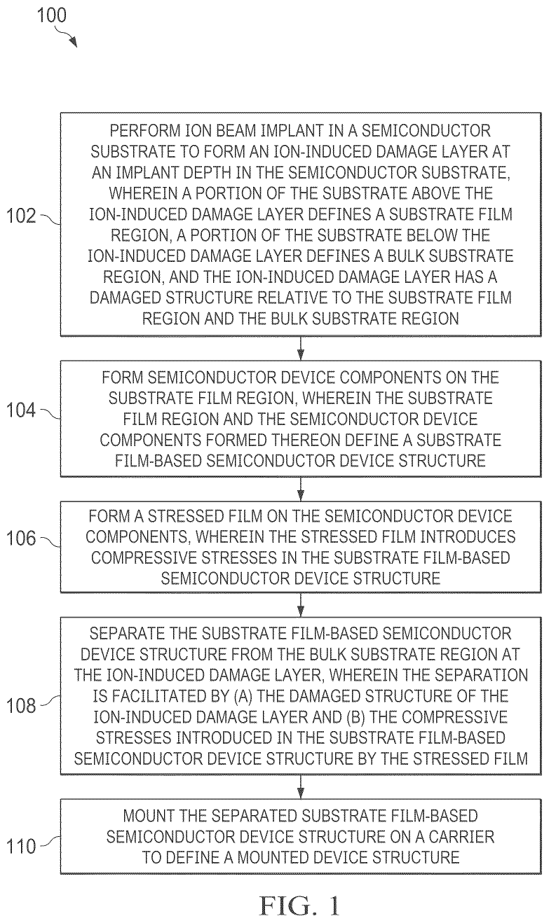

FIG. 1 is a flowchart 100 showing an example method of forming semiconductor devices. At 102, an ion beam implant (e.g., comprising H₂, helium, or other suitable ions) is performed in a semiconductor substrate to form an ion-induced damage layer at an implant depth in the semiconductor substrate, wherein a portion of the substrate above the ion-induced damage layer defines a substrate film region, a portion of the substrate below the ion-induced damage layer defines a bulk substrate region, and the ion-induced damage layer has a damaged structure relative to the substrate film region and the bulk substrate region.

In some examples, the semiconductor substrate may comprise silicon carbide (SiC), gallium nitride (GaN), or diamond. In some examples, the implant depth of the ion-induced damage layer is in the range of 0.35-1.0 μm below an upper surface of the semiconductor substrate.

At 104, semiconductor device components are formed on the substrate film region, wherein the substrate film region and the semiconductor device components formed thereon define a substrate film-based semiconductor device structure. In some example, forming semiconductor device components on the substrate film region may include growing an epitaxial region over the substrate film region, and forming metal structures over the epitaxial region.

At 106, a stressed film having inherent internal forces (e.g., tensile stresses and/or compressive stresses) is formed on the semiconductor device components, for example by depositing a conformal dielectric material over the semiconductor device components, or alternatively by attaching a pre-formed stressed film to the semiconductor device components. The stressed film introduces internal forces (e.g., tensile stresses and/or compressive stresses) in the substrate film-based semiconductor device structure. In some examples, the stressed film comprises silicon nitride (Si₃N₄), which may exhibit inherent tensile stresses.

At 108, the substrate film-based semiconductor device structure is separated from the bulk substrate region at the ion-induced damage layer. The separation of the substrate film-based semiconductor device structure from the bulk substrate region is facilitated by (a) the damaged structure of the ion-induced damage layer and (b) the internal forces introduced in the substrate film-based semiconductor device structure by the stressed film. A thickness of the original semiconductor substrate is thereby reduced at least by a thickness of substrate film region.

At 110, the separated substrate film-based semiconductor device structure is mounted on a carrier to define a mounted device structure.

In some examples, a transfer device may be secured to the stressed film prior to separating the substrate film-based semiconductor device structure from the bulk substrate region at 108, and the transfer device may be removed after mounting the separated substrate film-based semiconductor device structure on the carrier at 110. In some examples, the stressed film is also removed (e.g., together with the transfer device or separately from the removal of the transfer device) from the semiconductor device components.

In some examples, the mounted device structure may be diced to form a plurality of discrete devices.

In some examples, the bulk substrate region separated from the substrate film-based semiconductor device structure at 108 may be reused in one or more further instances of the method 100 to form additional devices, e.g., wherein the thickness of the bulk substrate region is further reduced during each successive instance of the method 100.

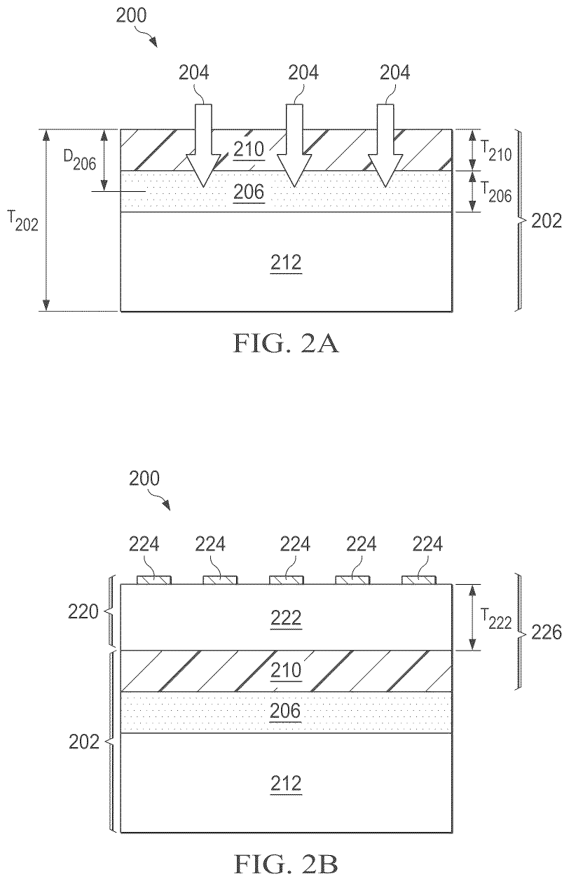

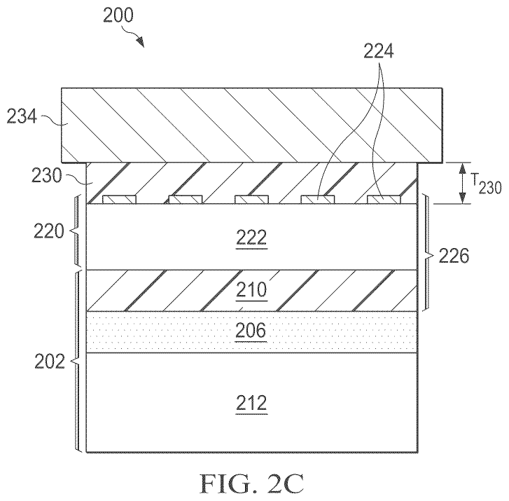

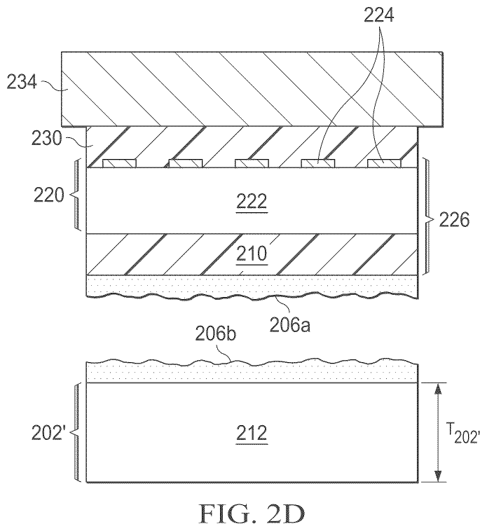

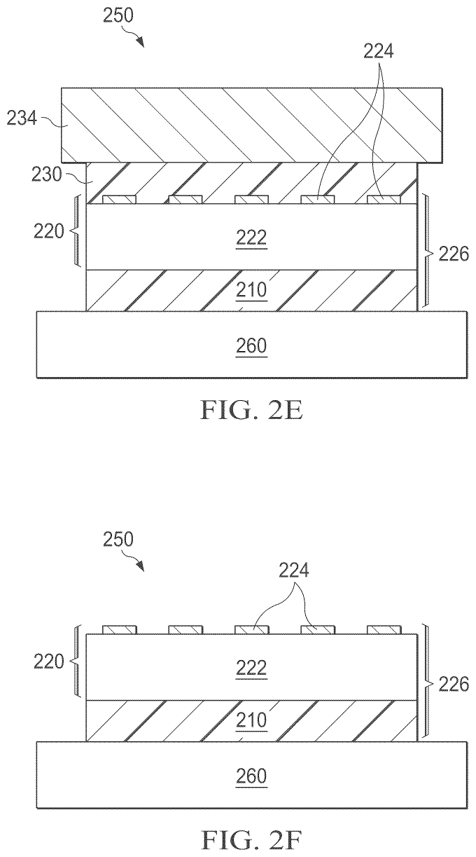

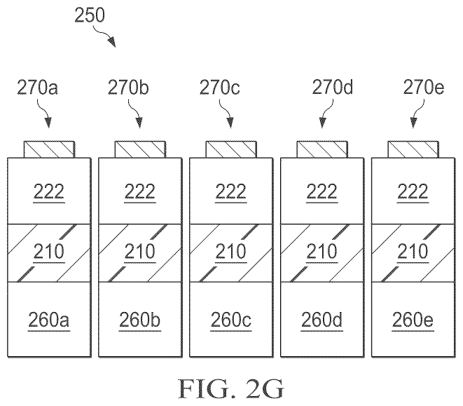

FIGS. 2A-2G are a series of cross-sectional side views illustrating an example method for forming semiconductor devices. The method shown in FIGS. 2A-2G may correspond with method 100 shown in FIG. 1 and discussed above, along with additional details.

As shown in FIG. 2A, a structure 200 may include a semiconductor substrate 200, e.g., comprising silicon carbide (SiC), gallium nitride (GaN), or diamond. In some examples, the semiconductor substrate 200 may have a thickness T₂₀₂ in the range of 100-500 μm, for example about 350 μm.

An ion beam implant, indicated at 204, is performed in the semiconductor substrate 202 to form an ion-induced damage layer 206 at an implant depth D₂₀₆ in the semiconductor substrate 202. In some examples, the ion beam implant may comprise an implant of H₂, helium, or other suitable ions, with an ion energy in the range of 55-180 keV. The type of implant ions used may depend on the material of the semiconductor substrate 202. For example, He ions may be used for a semiconductor substrate 202 comprising SiC or diamond.

A portion of the semiconductor substrate 202 above the ion-induced damage layer 206 defines a substrate film region 210 (i.e., a thin upper layer of the semiconductor substrate 202), and a portion of the semiconductor substrate 202 below the ion-induced damage layer 206 defines a bulk substrate region 212. As discussed below (e.g., with reference to FIG. 2D), the ion-induced damage layer 206 may be used to facilitate a separation of the upper substrate film region 210 from the bulk substrate region 212.

The ion-induced damage layer 106 has a damaged structure relative to the substrate film region 210 and the bulk substrate region 212. In some examples, implant depth D₂₀₆ of the ion-induced damage layer 106, e.g., measured from an upper surface of the semiconductor substrate 202 to a vertical midpoint of the ion-induced damage layer 206, is in the range of 0.35 μm to 1.0 μm (350-1000 nm). The implant depth D₂₀₆ may be controlled by selecting the implant energy level and/or other parameters of the ion beam implant 204. For example, an ion implant performed with an ion energy of 65 keV may provide an implant depth D₂₀₆ in the range of 0.35-0.45 μm (350-450 nm), whereas an ion implant performed with an ion energy of 140 keV may provide an implant depth D₂₀₆ in the range of 0.75-0.85 μm (750-850 nm).

In some examples, the ion-induced damage layer 106 may have a thickness T₂₀₆ in the range of 10-90 nm for example in the range of 20-50 nm.

In view of the example ranges of the implant depth D₂₀₆ and thickness T₂₀₆ of the ion-induced damage layer 106, the substrate film region 210 above the ion-induced damage layer 106 may have a thickness T₂₀₆ in the range of 0.345-0.995 μm (345-995 nm).

As shown in FIG. 2B, semiconductor device components 220 may be formed on the substrate film region 210. Semiconductor device components 220 may include, for example, one or more structures of at least one bipolar power device (e.g., at least one transistor, thyristor, or pin diode, without limitation) and/or at least one unipolar device (e.g., at least one MOSFET or Junction Barrier Schottky (JBS) device, without limitation). Some semiconductor device components 220 may comprise metal structures, e.g., formed in one or more metal layers.

In some examples, e.g., as shown in FIG. 2B, forming semiconductor device components 220 may include (a) growing an epitaxial region 222 (e.g., including or defining structures of respective semiconductor device components 220) over the substrate film region 210 and (b) forming metal structures 224 over the epitaxial region 222. In some examples, the epitaxial region 222 may have a thickness T₂₂₂ in the range of 3-50 μm.

As shown in FIG. 2B, the substrate film region 210 and the semiconductor device components 220 formed thereon collectively define a substrate film-based semiconductor device structure 226.

As shown in FIG. 2C, a stressed film 230 is formed on the substrate film-based semiconductor device structure 226. The stressed film 230 may comprise a film exhibiting internal forces (e.g., tensile stresses and/or compressive stresses), which introduces internal forces in the substrate film-based semiconductor device structure 226 on which it is formed. In some examples, the stressed film 230 comprises silicon nitride (Si₃N₄), e.g., having a thickness T₂₃₀ in the range of 10-20 nanometers, and in some examples, in the range of 25-50 nanometers.

In some examples, the stressed film 230 is formed by depositing a conformal dielectric material (e.g., silicon nitride) over the semiconductor device components, wherein the conformal dielectric material may at least partially flow into spaces between respective structures of respective semiconductor device components 220.

In other examples, the stressed film 230 is formed by attaching a pre-formed stressed film (e.g., comprising silicon nitride) to the substrate film-based semiconductor device structure 226 (e.g., to exposed surfaces of respective semiconductor device components 220), for example using a suitable adhesive or bonding process. The internal forces in the stressed film 230 (e.g., tensile stresses and/or compressive stresses) may inherently introduce internal forces (e.g., tensile stresses and/or compressive stresses) in underlying structures and/or layers, for example including the epitaxial layer 220, upper substrate film region 210 and/or ion-induced damage layer 206. These internal forces introduced by the stressed film 230 may facilitate a separation of the upper substrate film region 210 from the bulk substrate region 212, as discussed below.

In some examples, a transfer device 234 (e.g., a transfer stamp) may be secured to an upper side of the stressed film 230, for example using a tape or other adhesive, or using vacuum/suction force in the case of a transfer device 234 comprising a vacuum chuck.

As shown in FIG. 2D, the substrate film-based semiconductor device structure 226 (along with the stressed film 230 and transfer device 234 formed/secured thereon) is separated from the bulk substrate region 212 at the ion-induced damage layer 206. For example, the transfer device 234 (e.g., transfer stamp) may be used to lift the substrate film-based semiconductor device structure 226 off the bulk substrate region 212, which bulk substrate region 212 may remain secured to a mounting apparatus. The separation of the substrate film-based semiconductor device structure 226 from the bulk substrate region 212 (at the ion-induced damage layer 206) may be facilitated by (a) the damaged (weakened) structure of the ion-induced damage layer 206 and (b) the internal forces (e.g., tensile stresses and/or compressive stresses) introduced in the substrate film-based semiconductor device structure 226 by the stressed film 230. For example, the internal forces may cause the substrate film-based semiconductor device structure 226 to contract, buckle, bow, or curl, to thereby initiate or facilitate a separation at the ion-induced damage layer 206.

As shown, a first partial portion 206a of the ion-induced damage layer 206 may remain adhered to the upper substrate film region 210, while a second partial portion 206b of the ion-induced damage layer 206 may remain adhered to the bulk substrate region 212.

In some examples, the bulk substrate region 212 may define a reduced-thickness semiconductor substrate 202′ which may be reused to form additional devices by repeating the processes shown in FIGS. 2A-2G with the reduced-thickness semiconductor substrate 202′. In some examples, the second partial portion 206b of the ion-induced damage layer 206 may be removed (e.g., by a chemical etch process) before reusing the bulk substrate region 212 (reduced-thickness semiconductor substrate 202′). In this manner, a semiconductor substrate (e.g., an SiC, GaN, or diamond wafer substrate) may be reused multiple times to produce multiple groups of devices, wherein a thin layer of the semiconductor substrate is removed during each iteration. The thin layer of the semiconductor substrate removed during each iteration may comprise at least the upper substrate film region 210 and the ion-induced damage layer 206.

As shown in FIG. 2E, the transfer device 234 may carry and mount the separated substrate film-based semiconductor device structure 226 on a carrier 260 (e.g., a die carrier), to define a mounted device structure 250. The substrate film-based semiconductor device structure 226 may be bonded to the carrier 260, e.g., using a highly thermally and electrically conductive adhesive. In some examples, the carrier 260 may comprise a material having high thermal and electrical conductivity, for example, polycrystalline SiC, copper, or other suitable material. In other examples, the carrier 260 may comprise a dielectric substrate.

In some examples, the first partial portion 206a on the bottom surface of the ion-induced damage layer 206 may be maintained (i.e., not removed), as the material of the ion-induced damage layer 206 may improve a thermal and/or electrical connection between the upper substrate film region 210 and the carrier 230. In other examples, the first partial portion 206a may be cleaned or otherwise removed from the bottom surface of the ion-induced damage layer 206 before mounting the substrate film-based semiconductor device structure 226 on the carrier 260.

As shown in FIG. 2F, the transfer device 234 may be removed from the mounted device structure 250, e.g., by detaching the transfer device 234 from the stressed film 230. The stressed film 230 may then be removed, e.g., by performing a wet etch.

As shown in FIG. 2G, a dicing or cutting process may be performed to dice (cut) the mounted device structure 250 into a plurality of discrete devices 270a-270e, each mounted on a respective die carrier structure 260a-260e.

Although example embodiments have been described above, other variations and embodiments may be made from this disclosure without departing from the spirit and scope of these embodiments.

1. A method, comprising:
performing an ion beam implant in a semiconductor substrate to form an ion-induced damage layer at an implant depth in the semiconductor substrate, wherein a portion of the semiconductor substrate above the ion-induced damage layer defines a substrate film region, a portion of the semiconductor substrate below the ion-induced damage layer defines a bulk substrate region, and the ion-induced damage layer has a damaged structure relative to the substrate film region and the bulk substrate region;
forming semiconductor device components on the substrate film region, wherein the substrate film region and the semiconductor device components formed thereon define a substrate film-based semiconductor device structure;
forming a stressed film on the semiconductor device components, wherein the stressed film introduces internal forces in the substrate film-based semiconductor device structure;
separating the substrate film-based semiconductor device structure from the bulk substrate region at the ion-induced damage layer, wherein the separation is facilitated by (a) the damaged structure of the ion-induced damage layer and (b) the internal forces introduced in the substrate film-based semiconductor device structure by the stressed film; and
mounting the separated substrate film-based semiconductor device structure on a carrier to define a mounted device structure.

2. The method of claim 1, comprising:
securing a transfer device to the stressed film prior to separating the substrate film-based semiconductor device structure from the bulk substrate region; and
removing the transfer device after mounting the separated substrate film-based semiconductor device structure on the carrier.

3. The method of claim 1, wherein the semiconductor substrate comprises silicon carbide, gallium nitride, or diamond.

4. The method of claim 1, wherein the implant depth of the ion-induced damage layer is in the range of 0.35-1.0 μm below an upper surface of the semiconductor substrate.

5. The method of claim 1, comprising removing the stressed film from the semiconductor device components.

6. The method of claim 1, comprising dicing the mounted device structure to form a plurality of discrete devices.

7. The method of claim 1, wherein forming the stressed film on the semiconductor device components comprises depositing a conformal dielectric material over the semiconductor device components.

8. The method of claim 1, wherein forming the stressed film on the semiconductor device components comprises attaching a pre-formed stressed film to the semiconductor device components.

9. The method of claim 1, wherein the stressed film comprises silicon nitride.

10. The method of claim 1, wherein forming semiconductor device components on the substrate film region comprises:
growing an epitaxial region over the substrate film region; and
forming metal structures over the epitaxial region.

11. The method of claim 1, comprising after separating the substrate film-based semiconductor device structure from the bulk substrate region, using the separated bulk substrate region to form additional devices.

12. A method, comprising:
forming semiconductor device components on a semiconductor substrate to define a semiconductor device structure;
forming a stressed film over the semiconductor device components, wherein the stressed film introduces internal forces in a substrate film region of the semiconductor substrate;
separating a substrate film region of the semiconductor substrate from an underlying bulk substrate region of the semiconductor substrate, the separated substrate film region carrying the semiconductor device components to collectively define a substrate film-based semiconductor device structure;
wherein the separation of the substrate film region from the underlying bulk substrate region is facilitated by the internal forces introduced in the substrate film region of the semiconductor substrate by the stressed film; and
mounting the separated substrate film-based semiconductor device structure on a carrier.

13. The method of claim 12, wherein the stressed film comprises silicon nitride.

14. The method of claim 12, comprising:
performing an ion beam implant in the semiconductor substrate to form an ion-induced damage layer at an implant depth in the semiconductor substrate, wherein a portion of the semiconductor substrate above the ion-induced damage layer defines the substrate film region, and a portion of the semiconductor substrate below the ion-induced damage layer defines the bulk substrate region,
wherein the ion-induced damage layer has a damaged structure relative to the substrate film region and the bulk substrate region.

15. The method of claim 14, wherein the separation of the substrate film region from the underlying bulk substrate region is facilitated by the damaged structure of the ion-induced damage layer.

16. The method of claim 12, wherein forming the stressed film over the semiconductor device components comprises depositing a conformal dielectric material over the semiconductor device components.

17. The method of claim 12, comprising:
securing a transfer device to the stressed film prior to separating the substrate film region from the underlying bulk substrate region; and
removing the transfer device after mounting the separated substrate film-based semiconductor device structure on the carrier.

18. The method of claim 12, wherein forming semiconductor device components on the semiconductor substrate comprises:
growing an epitaxial region over the substrate film region; and
forming metal structures over the epitaxial region.

19. A device structure formed by a process comprising:
performing an ion beam implant in a semiconductor substrate to form an ion-induced damage layer at an implant depth in the semiconductor substrate, wherein a portion of the semiconductor substrate above the ion-induced damage layer defines a substrate film region, a portion of the semiconductor substrate below the ion-induced damage layer defines a bulk substrate region, and the ion-induced damage layer has a damaged structure relative to the substrate film region and the bulk substrate region;
forming semiconductor device components on the substrate film region, wherein the substrate film region and the semiconductor device components formed thereon define a substrate film-based semiconductor device structure;
forming a stressed film on the semiconductor device components, wherein the stressed film introduces internal forces in the substrate film-based semiconductor device structure;
separating the substrate film-based semiconductor device structure from the bulk substrate region at the ion-induced damage layer, wherein the separation is facilitated by (a) the damaged structure of the ion-induced damage layer and (b) the internal forces introduced in the substrate film-based semiconductor device structure by the stressed film; and
mounting the separated substrate film-based semiconductor device structure on a carrier to define a mounted device structure.
